(19) United States
(12) Patent Application Publication
(10) Pub. No.: US 2020/0220323 A1
(43) Pub. Date: Jul. 9, 2020

(54) OPTICAL MODULE

(71) Applicant: SUMITOMO ELECTRIC INDUSTRIES, LTD., Osaka-shi, Osaka (JP)

(72) Inventor: Hiromi NAKANISHI, Osaka-shi (JP)

(73) Assignee: SUMITOMO ELECTRIC INDUSTRIES, LTD., Osaka-shi, Osaka (JP)

(21) Appl. No.: 16/648,576

(22) PCT Filed: Sep. 7, 2018
(86) PCT No.: PCT/JP2018/033277

§ 371 Date: Mar. 18, 2020

(30) Foreign Application Priority Data
Sep. 29, 2017 (JP) 2017-190662

(51) Int. Cl. H01S 5/022; H01S 5/0683; H01S 5/40

(52) U.S. Cl. CPC H01S 5/02288; H01S 5/4012; H01S 5/0683; H01S 5/02292

(57) ABSTRACT

An optical module includes a light-forming unit that forms light. The light-forming unit includes: a base member; a semiconductor light-emitting element mounted on the base member and configured to emit light; a lens that is mounted on the base member, reflects part of the light emitted from the semiconductor light-emitting element, and transmits part of the light; and a light-receiving element mounted on the base member at a position that is between the semiconductor light-emitting element and the lens and is outside an irradiate region irradiated with the light emitted from the semiconductor light-emitting element toward the lens. The light-receiving element has a light-receiving surface and is configured to receive, on the light-receiving surface, part of the light reflected from the lens.

### TECHNICAL FIELD

The present disclosure relates to an optical module. The present application claims priority from Japanese Patent Application No. 2017-190662 filed on Sep. 29, 2017, the entire contents of which are incorporated herein by reference.

### BACKGROUND ART

There are known optical modules in which at least one semiconductor light-emitting element is disposed in a package (see, for example, PTL 1 to PTL 4). Such optical modules are used as light sources of various devices such as display devices, optical pickup devices, and optical communication devices.

### CITATION LIST

### Patent Literature

PTL 1: Japanese Unexamined Patent Application Publication No. 2009-93101

PTL 2: Japanese Unexamined Patent Application Publication No. 2007-328895

PTL 3: Japanese Unexamined Patent Application Publication No. 2007-17925

PTL 4: Japanese Unexamined Patent Application Publication No. 2007-65600

### SUMMARY OF INVENTION

The optical module of the present disclosure includes a light-forming unit that forms light. The light-forming unit includes: a base member; a semiconductor light-emitting element mounted on the base member and configured to emit light; a lens that is mounted on the base member, reflects part of the light emitted from the semiconductor light-emitting element, and transmits part of the light; and a light-receiving element mounted on the base member at a position that is between the semiconductor light-emitting element and the lens and is outside an irradiate region irradiated with the light emitted from the semiconductor light-emitting element toward the lens, the light-receiving element having a light-receiving surface and being configured to receive, on the light-receiving surface, part of the light reflected from the lens.

### BRIEF DESCRIPTION OF DRAWINGS

FIG. 1 is a schematic perspective view showing the structure of an optical module in embodiment 1.

FIG. 2 is a schematic perspective view showing the structure of the optical module in embodiment 1.

FIG. 3 is a schematic plan view showing the structure of the optical module in embodiment 1.

FIG. 4 is a schematic cross-sectional view showing the structure of the optical module in embodiment 1.

FIG. 5 is a schematic cross-sectional view showing the structure of an optical module in embodiment 2.

FIG. 6 is a schematic cross-sectional view showing the structure of a modification of the optical module in embodiment 2.

### DESCRIPTION OF EMBODIMENTS

Some conventional optical modules include a light-receiving element for measuring the amount of light from a semiconductor light-emitting element. When the light-receiving element directly receives the light emitted from the semiconductor light-emitting element, the light reflected from the light receiving surface of the light-receiving element becomes stray light. In this case, when the optical module is used, for example, as a display device, the stray light may appear on the surface of projection. It is preferable to avoid such a situation as much as possible.

### [Description of Embodiments of Present Disclosure]

First, embodiments of the present disclosure will be enumerated and described. An optical module according to the present disclosure includes a light-forming unit that forms light. The light-forming unit includes: a base member; a semiconductor light-emitting element mounted on the base member and configured to emit light; a lens that is mounted on the base member, reflects part of the light emitted from the semiconductor light-emitting element, and transmits part of the light; and a light-receiving element mounted on the base member at a position that is between the semiconductor light-emitting element and the lens and is outside an irradiate region irradiated with the light emitted from the semiconductor light-emitting element toward the lens, the light-receiving element having a light-receiving surface and being configured to receive, on the light-receiving surface, part of the light reflected from the lens.

In the optical module having the above structure, the light-receiving element receives part of the reflected light that is the light emitted from the semiconductor light-emitting element and reflected from the lens and can measure the amount of the light from the semiconductor light-emitting element. The intensity of the light emitted from the semiconductor light-emitting element can be adjusted based on the measured light amount. In this case, since the light-receiving element is disposed on the base member at a position that is between the semiconductor light-emitting element and the lens and is outside the irradiate region irradiated with the light emitted from the semiconductor light-emitting element, the light emitted from the semiconductor light-emitting element does not impinge directly on the light-receiving element. When the light-receiving element directly receives the light from the semiconductor light-emitting element, reflected light is generated. However, in the above case, such reflected light is not generated. This can prevent reflected light generated when light impinges directly on the light-receiving element from entering the lens and being outputted to the outside. In the above optical module, the occurrence of stray light can be prevented.

In the above optical module, the light-forming unit may be configured to include: a plurality of the semiconductor light-emitting elements mounted on the base member; a plurality of the lenses mounted on the base member and disposed so as to correspond to the respective semiconductor light-emitting elements; a plurality of the light-receiving elements mounted on the base member and disposed so as to correspond to the respective semiconductor light-emitting elements; and a filter that is disposed on the base member and multiplexes light beams from the plurality of semiconductor light-emitting elements. In this case, while the occurrence of stray light is prevented, the light beams emitted from the plurality of semiconductor light-emitting elements can be multiplexed and outputted from the optical module.

In the above optical module, the semiconductor light-emitting element may be a laser diode. In this case, variations in the wavelength of the outgoing light obtained can be small.

The output power of the light formed by the light-forming unit may be 50 mW or more. This optical module is applicable to display devices, optical pickup devices, etc.

In the above optical module, the base member may include a base plate, and the light-receiving element may be mounted directly on the base plate. In this case, the production process of the optical module can be simplified, and the optical module can be produced more easily.

In the above optical module, the light-receiving element may be mounted between an edge of the irradiated region and reflected light that is light traveling along the edge of the irradiated region and reflected from the lens.

In the above optical module, the light receiving surface may be inclined relative to an optical axis of the light so as to be oriented toward the lens. In this case, the reflected light reflected from the light receiving surface of the light-receiving element is prevented from re-entering the semiconductor light-emitting element, so that the occurrence of difficulty in controlling the output power of the semiconductor light-emitting element can be avoided.

An optical module according to the present disclosure includes: a semiconductor light-emitting element configured to emit light; a lens configured to reflect part of the light emitted from the semiconductor light-emitting element and transmit part of the light; and a light-receiving element configured to receive part of the light reflected from the lens at a position outside an irradiated region irradiated with the light emitted from the semiconductor light-emitting element toward the lens.

In the optical module having the above structure, the light-receiving element receives part of the reflected light that is the light emitted from the semiconductor light-emitting element and reflected from the lens and can measure the amount of the light from the semiconductor light-emitting element. The intensity of the light emitted from the semiconductor light-emitting element can be adjusted based on the measured light amount. In this case, since the light-receiving element is located at the position outside the emission region of the light from the semiconductor light-emitting element, the light emitted from the semiconductor light-emitting element does not impinge directly on the light-receiving element. When the light-receiving element directly receives the light from the semiconductor light-emitting element, reflected light is generated. However, in the above case, no such reflected light is generated. This can prevent reflected light generated when light impinges directly on the light-receiving element from entering the lens and being outputted to the outside. In the above optical module, the occurrence of stray light can be prevented.

### [Details of Embodiments of Present Disclosure]

### (Embodiment 1)

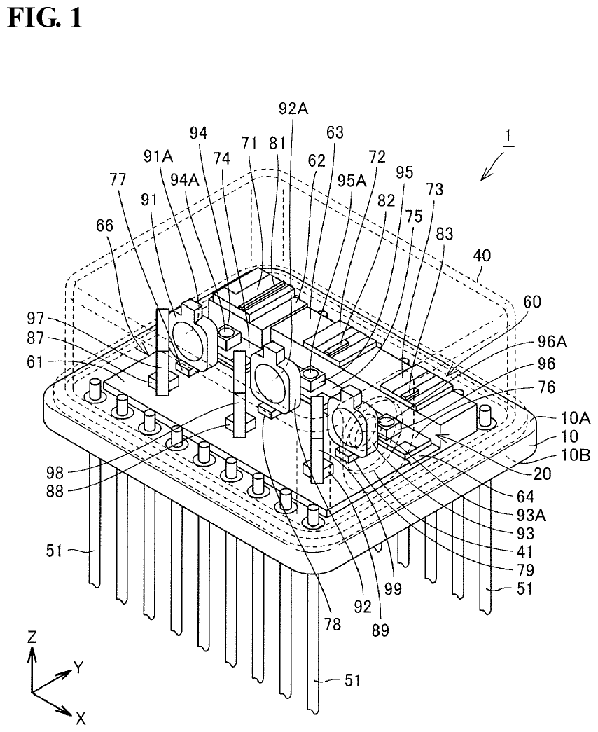

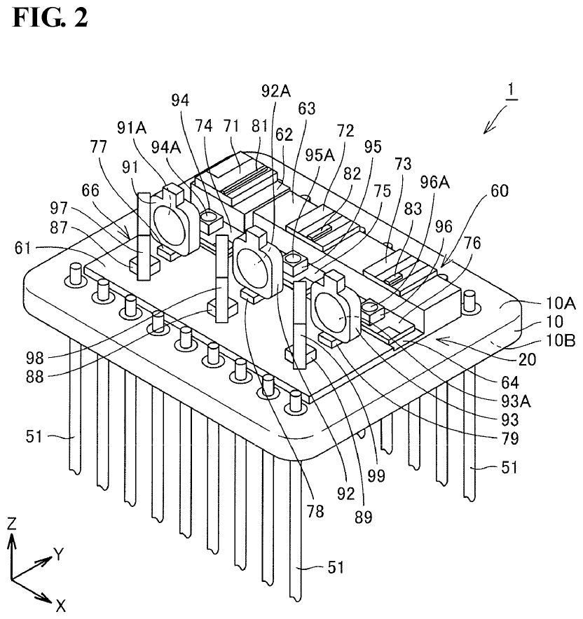

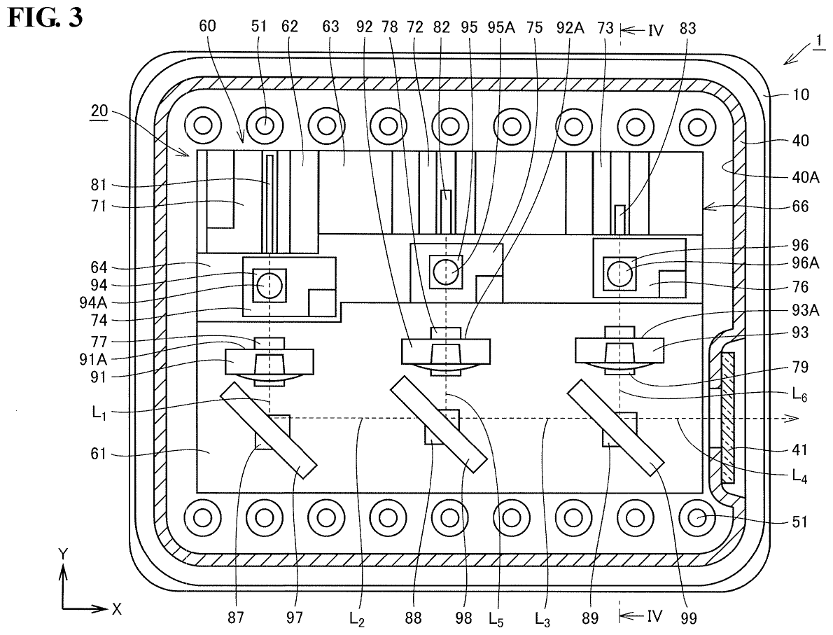

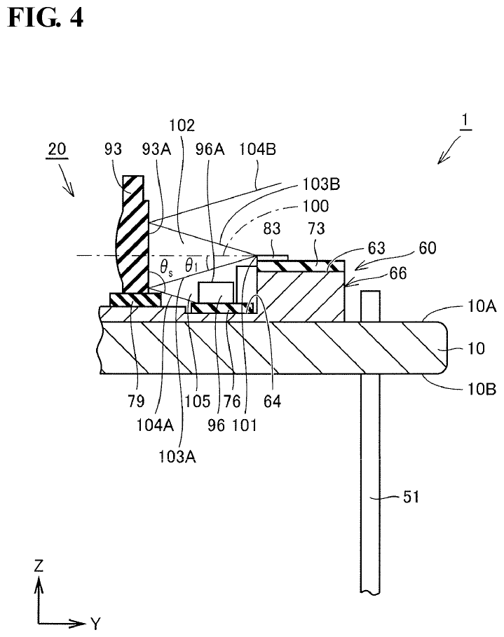

Next, embodiment 1, which is an embodiment of the optical module according to the present disclosure, will be described with reference to FIGS. 1 to 4. FIGS. 2 and 4 are illustrations with a cap 40 in FIG. 1 removed. FIG. 4 is a cross-sectional view taken along IV-IV in FIG. 3. The cross section shown in FIG. 4 is a plane extending along the YZ plane, and part of the optical module is omitted. In the following drawings, the same or corresponding components are denoted by the same reference numerals, and the description thereof may not be repeated.

Referring to FIGS. 1 to 4, the optical module 1 in embodiment 1 includes: a base 10 having a flat plate shape; a light-forming unit 20 serving as a light-emitting unit forming light and disposed on a first surface 10A of the base 10 that is located in a Z-axis direction; the cap 40 disposed in contact with the first surface 10A of the base 10 so as to cover the light-forming unit 20; and a plurality of lead pins 51 that pass through the base 10 so as to extend from its second surface 10B located in the Z-axis direction to the first surface 10A and protrudes from both the first surface 10A and the second surface 10B. The base 10 and the cap 40 are, for example, welded together to obtain an airtight state. Specifically, the light-forming unit 20 is hermetically sealed by the base 10 and the cap 40. A gas such as dry air with reduced water content or with water removed therefrom is sealed in the space surrounded by the base 10 and the cap 40. The cap 40 has an emission window 41 that allows the light from the light-forming unit 20 to pass through. A member forming the emission window 41 may have a flat plate shape in which surfaces disposed in the thickness direction (X axis direction) are parallel to each other. Alternatively, the member may have a lens shape that condenses or diffuses the light from the light-forming unit 20. The base 10 and the cap 40 form a protective member. The base 10 has a rectangular shape with four rounded corners in plan view (when viewed in the Z-axis direction) (see, in particular, FIG. 3). The cap 40 also has a rectangular shape with four rounded corners in plan view. The projected area of the base 10 when it is viewed in the Z-axis direction is larger than the projected area of the cap 40 when it is viewed in the Z-axis direction. Specifically, the outer circumference of the base 10 protrudes like a flange from the outer circumference of the cap 40.

The light-forming unit 20 includes a base member 60 including a base plate 66. The base plate 66 has a rectangular shape in plan view. The base plate 66 includes a base region 61, a first chip mounting region 62, a second chip mounting region 63, and a photodiode mounting region 64. The first chip mounting region 62 and the second chip mounting region 63 are arranged in the X axis direction. In the Y-axis direction, the photodiode mounting region 64 is disposed between the base region 61 and the first and second chip mounting regions 62 and 63 arranged in the X axis direction. The base region 61, the first chip mounting region 62, the second chip mounting region 63, and the photodiode mounting region 64 are each flat. The flat surfaces forming the base region 61, the first chip mounting region 62, the second chip mounting region 63, and the photodiode mounting region 64 are disposed so as to be parallel to each other in the Z-axis direction. The base member 60 includes, on the base plate 66, a first submount 71, a second submount 72, a third submount 73, a fourth submount 74, a fifth submount 75, and a sixth submount 76, which will be described later.

The thickness of the first chip mounting region 62 and the thickness of the second chip mounting region 63 are larger than the thickness of the base region 61. Therefore, the height of the first chip mounting region 62 and the height of the second chip mounting region 63 are larger than the height of the base region 61. The first chip mounting region 62 is taller than the second chip mounting region 63. The thickness of the photodiode mounting region 64 is smaller than the thicknesses of the base region 61, the first chip mounting region 62, and the second chip mounting region 63. Therefore, the height of the photodiode mounting region 64 is smaller than the height of the base region 61. The above height means the distance in the Z-axis direction with respect to an X-Y plane.

The first submount 71 having a flat plate shape is disposed on the first chip mounting region 62. A red laser diode 81 that is a semiconductor laser emitting red light and serving as a semiconductor light-emitting element is disposed on the first submount 71. The second submount 72 having a flat plate shape and the third submount 73 having a flat plate shape are disposed on the second chip mounting region 63. The second submount 72 and the third submount 73 are spaced apart from each other in the X axis direction. The second submount 72 is disposed closer to the first submount 71. A green laser diode 82 that is a semiconductor laser emitting green light and serving as a semiconductor light-emitting element is disposed on the second submount 72. A blue laser diode 83 that is a semiconductor laser emitting blue light and serving as a semiconductor light-emitting element is disposed on the third submount 73.

The heights of the optical axes of the red laser diode 81, the green laser diode 82, and the blue laser diode 83 (the distances between the optical axes and one surface of the base plate 66 that is used as a reference plane; the distances in the Z-axis direction from the reference plane) are adjusted by the first submount 71, the second submount 72, and the third submount 73, respectively, so as to coincide with each other. The red light has a wavelength of about 620 nm (nanometers) to about 750 nm, and the green light has a wavelength of about 495 nm to about 570 nm. The blue light has a wavelength of about 420 nm to about 495 nm.

A first lens support 77, a second lens support 78, and a third lens support 79 that protrude in a direction indicated by arrow Z are provided on the base region 61. A first lens 91, a second lens 92, and a third lens 93 are disposed on the first lens support 77, the second lens support 78, and the third lens support 79, respectively. The first lens 91, the second lens 92, and the third lens 93 have respective lens portions having respective flat surfaces 91A, 92A, and 93A on one side and respective lens surfaces on the other side. The first lens 91, the second lens 92, and the third lens 93 are disposed such that the flat surfaces 91A, 92A, and 93A of the lens portions face the red laser diode 81, the green laser diode 82, and the blue laser diode 83, respectively. The center axes of the lens portions, i.e., the optical axes of the lens portions, of the first lens 91, the second lens 92, and the third lens 93 are adjusted by the first lens support 77, the second lens support 78, and the third lens support 79, respectively, so as to be aligned with the optical axes of the red laser diode 81, the green laser diode 82, and the blue laser diode 83, respectively. The first lens 91, the second lens 92, and the third lens 93 change the spot sizes of light beams emitted from the red laser diode 81, the green laser diode 82, and the blue laser diode 83, respectively. The first lens 91, the second lens 92, and the third lens 93 change the spot sizes of the light beams emitted from the red laser diode 81, the green laser diode 82, and the blue laser diode 83, respectively, such that the spot sizes coincide with each other.

A first filter 97, a second filter 98, and a third filter 99 are disposed in the base region 61. The first filter 97, the second filter 98, and the third filter 99 are disposed on a first protruding region 87, a second protruding region 88, and a third protruding region 89, respectively, that are disposed in the base region 61 so as to protrude in the Z-axis direction and located in the emission directions of the red laser diode 81, the green laser diode 82, and the blue laser diode 83, respectively. The first filter 97, the second filter 98, and the third filter 99 each have a flat plate shape having principal surfaces parallel to each other. The first filter 97, the second filter 98, and the third filter 99 are, for example, wavelength selective filters. The first filter 97, the second filter 98, and the third filter 99 are dielectric multilayer filters. More specifically, the first filter 97 reflects red light. The second filter 98 transmits red light and reflects green light. The third filter 99 transmits red light and green light and reflects blue light. As described above, the first filter 97, the second filter 98, and the third filter 99 selectively transmit and reflect light beams having specific wavelengths. Therefore, the first filter 97, the second filter 98, and the third filter 99 multiplex the light beams emitted from the red laser diode 81, the green laser diode 82, and the blue laser diode 83.

The fourth submount 74, the fifth submount 75, and the sixth submount 76 are disposed in the photodiode mounting region 64. A first photodiode 94 serving as a first light-receiving element, a second photodiode 95 serving as a second light-receiving element, and a third photodiode 96 serving as a third light-receiving element are disposed on the fourth submount 74, the fifth submount 75, and the sixth submount 76, respectively. In the present embodiment, the light-receiving elements are disposed so as to correspond to their respective semiconductor light-emitting elements. The first photodiode 94, the second photodiode 95, and the third photodiode 96 are photodiodes capable of receiving red light, green light, and blue light, respectively. The first photodiode 94 is disposed between the red laser diode 81 and the first lens 91 in the emission direction of the red laser diode 81. The second photodiode 95 is disposed between the green laser diode 82 and the second lens 92 in the emission direction of the green laser diode 82. The third photodiode 96 is disposed between the blue laser diode 83 and the third lens 93 in the light emission direction of the blue laser diode 83. The heights (the distances in the Z-axis direction) of the first photodiode 94, the second photodiode 95, and the third photodiode 96 are adjusted by the fourth submount 74, the fifth submount 75, and the sixth submount 76, respectively.

The red laser diode 81, the first photodiode 94, the first lens 91, and the first filter 97 are aligned in the emission direction of the red laser diode 81 (aligned in the Y-axis direction). The green laser diode 82, the second photodiode 95, the second lens 92, and the second filter 98 are aligned in the emission direction of the green laser diode 82 (aligned in the Y-axis direction). The blue laser diode 83, the third photodiode 96, the third lens 93, and the third filter 99 are aligned in the emission direction of the blue laser diode 83 (aligned in the Y-axis direction). The emission direction of the red laser diode 81 extends in the emission directions of the green laser diode 82 and the blue laser diode 83. More specifically, the emission direction of the red laser diode 81, the emission direction of the green laser diode 82, and the emission direction of the blue laser diode 83 are parallel to each other. The principal surfaces of the first filter 97 are inclined relative to the emission direction of the red laser diode 81. More specifically, the principal surfaces of the first filter 97 are inclined 45° relative to the emission direction of the red laser diode 81 (the Y-axis direction). The principal surfaces of the second filter 98 are inclined relative to the emission direction of the green laser diode 82. More specifically, the principal surfaces of the second filter 98 are inclined 45° relative to the emission direction of the green laser diode 82 (the Y-axis direction). The principal surfaces of the third filter 99 are inclined relative to the emission direction of the blue laser diode 83. More specifically, the principal surfaces of the third filter 99 are inclined 45° relative to the emission direction of the blue laser diode 83 (the Y-axis direction).

The first photodiode 94 is mounted so as to be located outside the emission region of the light from the red laser diode 81. Moreover, the first photodiode 94 is mounted so as to receive part of reflected light that is the light emitted from the red laser diode 81 and reflected from the first lens 91. Specifically, the first photodiode 94 does not directly receive the light from the red laser diode 81. The second photodiode 95 is mounted so as to be located outside the emission region of the light from the green laser diode 82. Moreover, the second photodiode 95 is disposed at a position at which the second photodiode 95 receives part of reflected light that is the light emitted from the green laser diode 82 and reflected from the second lens 92. Specifically, the second photodiode 95 does not directly receive the light from the green laser diode 82. The third photodiode 96 is mounted so as to be located outside the emission region of the light from the blue laser diode 83. Moreover, the third photodiode 96 is disposed at a position at which the third photodiode 96 receives part of reflected light that is the light emitted from the blue laser diode 83 and reflected from the third lens 93. Specifically, the third photodiode 96 does not directly received the light from the blue laser diode 83.

Next, the placement positions of the first photodiode 94, the second photodiode 95, and the third photodiode 96 will be described in detail with reference mainly to FIG. 4. Specifically, the placement position of the third photodiode 96 will be described as an example. The placement positions of the first photodiode 94 and the second photodiode 95 are similar to the placement position of the third photodiode 96 relative to the blue laser diode 83 described below.

The blue laser diode 83 emits light toward the side on which the third lens 93 is disposed. The optical axis 100 of the emitted light is indicated by a dash-dot line in FIG. 4. The light emitted from the blue laser diode 83 is divergent light. Therefore, the light emitted from the blue laser diode 83 diverges from an emission portion 101 of the blue laser diode 83 toward the third lens 93. The irradiated region 102 irradiated with the light is a region between a lower edge 103A on the photodiode mounting region 64 side and an upper edge 103B located on the side opposite to the lower edge 103 A in the cross section shown in FIG. 4. The angle between the optical axis 100 of the light emitted from the blue laser diode 83 and the lower edge 103A is denoted by θ₁. The thickness direction of the base plate 66 is the Z-axis direction. When viewed in the Y-axis direction, the light emitted from the blue laser diode 83 has an elliptical shape whose edge is slightly elongated in the Z-axis direction.

The light emitted from the blue laser diode 83 reaches the third lens 93 and is incident on the lens portion of the third lens 93. Part of the light emitted from the blue laser diode 83 is reflected from the surface 93A of the third lens 93 that is located on the side toward the blue laser diode 83. The ratio of the amount of the reflected light to the amount of the emitted light is about 1 to about 2%. The light emitted from the blue laser diode 83 is divergent light, and the light reflected from the surface 93A also diverges in the Z-axis direction as indicated by reflected light 104A corresponding to the lower edge 103A and reflected light 104B at the upper edge 103B in FIG. 4. The angle of divergence of the reflected light is shown by the angle θs between the line indicating the surface 93A and the reflected light 104A in FIG. 4.

The third photodiode 96 is disposed on the sixth submount 76 such that a light receiving surface 96A that receives light whose light amount is to be measured is oriented in the Z-axis direction. The light receiving surface 96A is flat. Specifically, the light receiving surface 96A of the third photodiode 96 is disposed so as to be parallel to the optical axis 100.

The third photodiode 96 is located outside the irradiated region 102 irradiated with the light from the blue laser diode 83. Specifically, the third photodiode 96 is disposed such that the light receiving surface 96A is located outside the lower edge 103A of the light. The third photodiode 96 is disposed at a position at which the third photodiode 96 receives part of the reflected light that is the light emitted from the blue laser diode 83 and reflected from the third lens 93, specifically from the surface 93A of the third lens 93 that is disposed on the side toward the blue laser diode 83. Specifically, the third photodiode 96 is disposed at a position at which the light receiving surface 96A can receive part of the reflected light indicated by a region 105 between the lower edge 103A and the reflected light 104A of the light at the lower edge 103A.

The first photodiode 94 is located outside the irradiated region irradiated with the light from the red laser diode 81 toward the first lens 91, as is the third photodiode 96. The first photodiode 94 is disposed at a position at which the first photodiode 94 can receive part of the reflected light that is the light emitted from the red laser diode 81 and reflected from the first lens 91. The second photodiode 95 is located outside the irradiated region irradiated with the light from the green laser diode 82 toward the second lens 92, as is the third photodiode 96. The second photodiode 95 is disposed at a position at which the second photodiode 95 can receive part of the reflected light that is the light emitted from the green laser diode 82 and reflected from the second lens 92.

Next, the operation of the optical module 1 in the present embodiment will be described. The red light emitted from the red laser diode 81 travels along an optical path L₁. The red light passing above the first photodiode 94 is incident on the surface 91A of the lens portion of the first lens 91, and the spot size of the light is changed. Specifically, the red light emitted from the red laser diode 81 is converted to, for example, collimated light. Part of the light emitted from the red laser diode 81 is reflected from the surface 91A of the lens portion of the first lens 91. A light receiving surface 94A of the first photodiode 94 receives part of the reflected light, and the intensity of the red light emitted from the red laser diode 81 is determined using the received red light. The intensity of the red light is adjusted based on the difference between the determined intensity of the light and the target intensity of the emitted light. The red light whose spot size has been changed by the first lens 91 travels along the optical path L₁ and is incident on the first filter 97. Since the first filter 97 reflects the red light, the light emitted from the red laser diode 81 travels along an optical path L₂ and is incident on the second filter 98. Since the second filter 98 transmits the red light, the light emitted from the red laser diode 81 further travels along an optical path L₃ and is incident on the third filter 99. Since the third filter 99 transmits the red light, the light emitted from the red laser diode 81 further travels along an optical path L₄, passes through the emission window 41 of the cap 40, and is emitted to the outside of the optical module 1.

The green light emitted from the green laser diode 82 travels along an optical path L₅. The green light passing above the second photodiode 95 is incident on the surface 92A of the lens portion of the second lens 92, and the spot size of the light is changed. Specifically, the green light emitted from the green laser diode 82 is converted to, for example, collimated light. Part of the light emitted from the green laser diode 82 is reflected from the surface 92A of the lens portion of the second lens 92. A light receiving surface 95A of the second photodiode 95 receives part of the reflected light, and the intensity of the red light emitted from the green laser diode 82 is determined using the received green light. The intensity of the green light is adjusted based on the difference between the determined intensity of the light and the target intensity of the emitted light. The green light whose spot size has been changed by the second lens 92 travels along the optical path L₅ and is incident on the second filter 98. Since the second filter 98 reflects the green light, the light emitted from the green laser diode 82 joins into the optical path L₃. Therefore, the green light is multiplexed with the red light, travels along the optical path L₃, and is incident on the third filter 99. Since the third filter 99 transmits the green light, the light emitted from the green laser diode 82 further travels along the optical path L₄, passes through the emission window 41 of the cap 40, and is emitted to the outside of the optical module 1.

The blue light emitted from the blue laser diode 83 travels along an optical path L₆. The blue light passing above the third photodiode 96 is incident on the surface 93A of the lens portion of the third lens 93, and the spot size of the light is changed. Specifically, the blue light emitted from the blue laser diode 83 is converted to, for example, collimated light. Part of the light emitted from the blue laser diode 83 is reflected from the surface 93A of the lens portion of the third lens 93. The light receiving surface 96A of the third photodiode 96 receives part of the reflected light, and the intensity of the blue light emitted from the blue laser diode 83 is determined using the received blue light. The intensity of the blue light is adjusted based on the difference between the determined intensity of the light and the target intensity of the emitted light. The blue light whose spot size has been changed by the third lens 93 travels along the optical path L₆ and is incident on the third filter 99. Since the third filter 99 reflects the blue light, the light emitted from the blue laser diode 83 joins into the optical path L₄. Therefore, the blue light is multiplexed with the red light and the green light, travels along the optical path L₄, passes through the emission window 41 of the cap 40, and is emitted to the outside of the optical module 1.

The light formed by multiplexing the red light, the green light, and the blue light is emitted from the emission window 41 of the cap 40 in the manner described above. The power of the light formed by the light-forming unit 20 is, for example, 50 mW or more.

In the optical module 1 having the above structure, the first photodiode 94 receives part of the reflected light that is the light emitted from the red laser diode 81 and reflected from the first lens 91 and can measure the amount of the light emitted from the red laser diode 81. The intensity of the light emitted from the red laser diode 81 can be adjusted based on the measured light amount. In this case, the first photodiode 94 is disposed on the base member 60 at a position that is between the red laser diode 81 and the first lens 91 and is outside the emission region of the light from the red laser diode 81. Therefore, the light emitted from the red laser diode 81 does not impinge directly on the first photodiode 94. If the first photodiode 94 directly receives the light from the red laser diode 81, reflected light is generated. However, in the above case, no such reflected light is generated. Since no light impinges directly on the first photodiode 94, no reflected light is generated, and therefore such reflected light can be prevented from entering the first lens 91 and being outputted to the outside. The same applies to the second photodiode 95 and the third photodiode 96. Therefore, in the above optical module 1, the occurrence of stray light can be prevented.

In the optical module 1 in the present embodiment, the first photodiode 94 corresponding to the red laser diode 81 and the second photodiode 95 corresponding to the green laser diode 82 are disposed similarly to the third photodiode 96 corresponding to the blue laser diode 83. Therefore, the occurrence of stray light can be prevented for all the red light, the green light, and the blue light.

In the optical module 1 in the present embodiment, the third photodiode 96 is disposed in the region 105 between the lower edge 103A of the irradiated region 102 irradiated with the light emitted from the blue laser diode 83 and the reflected light 104A that is the light at the lower edge 103A and reflected from the surface 93A. In other words, the third photodiode 96 serving as a light-receiving element is mounted between the lower edge 103A that is an edge of the light irradiated region 102 and the light 104A that is the light travelling along the edge of the irradiated region and reflected from the lens 93. Therefore, the third photodiode 96 can receive the reflected light more appropriately.

In the optical module 1 in the present embodiment, the red laser diode 81, the green laser diode 82, and the blue laser diode 83 serve as semiconductor light-emitting elements. Therefore, variations in the wavelengths of the outgoing light obtained can be small.

### (Embodiment 2)

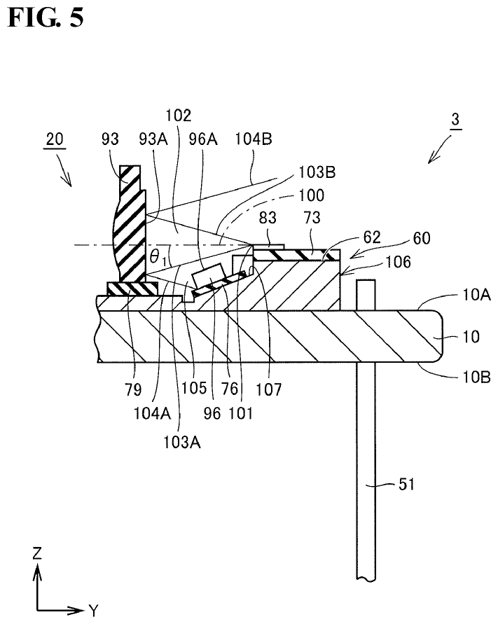

In embodiment 1, the light receiving surfaces 94A, 95A, and 96A are formed into flat surfaces extending along the optical axes. However, this is not a limitation. The light receiving surfaces 94A, 95A, and 96A may be inclined relative to the optical axes. Referring next to FIG. 5, embodiment 2, which is another embodiment of the optical module 1 according to the present disclosure, will be described.

Referring to FIG. 5, unlike the case shown in FIG. 4, a photodiode mounting region 107 is inclined relative to the optical axis 100. Therefore, when a third photodiode 96 having the same shape as the third photodiode 96 shown in FIG. 4 etc. is mounted on the photodiode mounting region 107, the third photodiode 96 is also inclined. In this case, the third photodiode 96 is inclined such that its light receiving surface 96A is oriented toward the third lens 93.

In the above structure, reflected light reflected from the light receiving surface 96A is prevented from entering the blue laser diode 83. Therefore, the occurrence of difficulty in controlling the output of the blue laser diode 83 can be avoided. Moreover, the region between the blue laser diode 83 and the third lens 93 can be efficiently used to dispose the third photodiode 96. Specifically, when the distance between the blue laser diode 83 and the third lens 93 in the Y-axis direction is small, if the third photodiode 96 is disposed such that the light receiving surface 96A is parallel to the optical axis 100 of the light emitted from the blue laser diode 83 as shown in FIG. 4, part of the light receiving surface 96A may intersect the lower edge 103A. However, when the photodiode mounting region 107 is inclined to incline the light receiving surface 96A relative to the optical axis, the light receiving surface 96A can be disposed outside the lower edge 103A.

In the above embodiment, at least one of the light receiving surfaces 94A, 95A, and 96A of the first photodiode 94, the second photodiode 95, and the third photodiode 96 may be inclined relative to the optical axis 100, and the rest may be parallel to the optical axis 100. Specifically, at least one of the first photodiode 94, the second photodiode 95, and the third photodiode 96 may have the structure shown in FIG. 5, and the rest may have the structure shown in FIG. 4.

In the above embodiment, the photodiode mounting region 107 is inclined to incline the light receiving surface 96A of the third photodiode 96. However, this is not a limitation. For example, the sixth submount 76 may have an inclined surface, and the third photodiode 96 may be mounted on the sixth submount 76 to incline the light receiving surface 96A. A third photodiode 96 having an inclined light receiving surface 96A may be used.

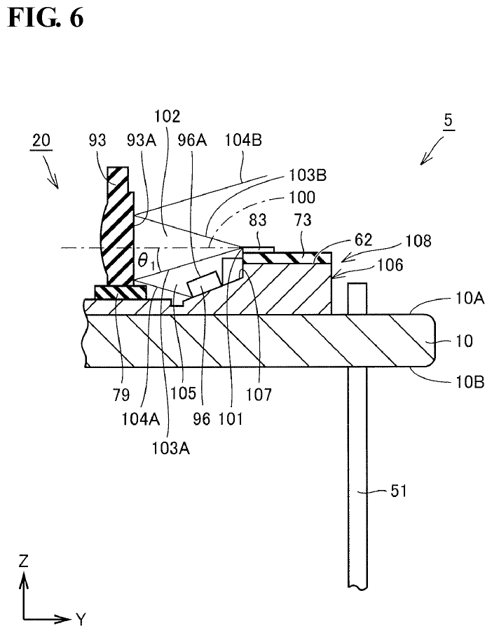

The following structure may be used. FIG. 6 is an illustration showing a modification of embodiment 2. Referring to FIG. 6, FIG. 6 differs from FIG. 5 in that the sixth submount 76 disposed between the third photodiode 96 and the photodiode mounting region 107 is omitted. Specifically, the third photodiode 96 may be mounted directly on a base plate 106. Similarly, the first photodiode 94 and the second photodiode 95 may be mounted directly on the base plate 106. Specifically, the fourth submount 74, the fifth submount 75, and the sixth submount 76 may be omitted, and the first photodiode 94, the second photodiode 95, and the third photodiode 96 may be disposed directly on the photodiode mounting region 107. In this case, the production process is simplified, and an optical module 5 can be produced more easily. Of course, in embodiment 1 shown in FIGS. 1 to 4 also, the third photodiode 96 etc. may be mounted directly on the base plate 66.

In the above embodiments, the optical modules 1, 3, and 5 each include the red laser diode 81, the green laser diode 82, and the blue laser diode 83, but this is not a limitation. The optical modules 1, 3, and 5 may each include at least one color laser diode, i.e., at least one of the red laser diode 81, the green laser diode 82, and the blue laser diode 83.

The power of the light formed by the light-forming unit 20 is, for example, 50 mW or more. Such optical modules 1, 3, and 5 are applicable to display devices, optical pickup devices, etc.

It should be understood that the embodiments disclosed herein are illustrative in all aspects and non-restrictive in every respect. The scope of the present invention is defined not by the above description but by the scope of the claims. It is intended that the present invention includes all modifications which fall within the scope and meanings equivalent to the scope of the claims.

### REFERENCE SIGNS LIST

1, 3, 5 optical module

10 base

10A, 10B, 91A, 92A, 93A surface

20 light-forming unit

40 cap

41 emission window

51 lead pin

60, 108 base member

61 base region

62 first chip mounting region, 63 second chip mounting region

64, 107 photodiode mounting region

66, 106 base plate

71 first submount, 72 second submount, 73 third submount

74 fourth submount, 75 fifth submount, 76 sixth submount

77 first lens support, 78 second lens support, 79 third lens support

81 red laser diode, 82 green laser diode, 83 blue laser diode

87 first protruding region, 88 second protruding region, 89 third protruding region

91 first lens, 92 second lens, 93 third lens

94 first photodiode, 95 second photodiode, 96 third photodiode

94A, 95A, 96A light receiving surface

97 first filter, 98 second filter, 99 third filter

100 optical axis, 101 emission portion, 102 irradiated region

103A lower edge, 103B upper edge

104A, 104B reflected light

105 region

1. An optical module comprising
a light-forming unit that forms light,
wherein the light-forming unit includes:
a base member;
a semiconductor light-emitting element mounted on the base member and configured to emit light;
a lens mounted on the base member, configured to reflect part of the light emitted from the semiconductor light-emitting element, and configured to transmit part of the light; and
a light-receiving element mounted on the base member at a position that is between the semiconductor light-emitting element and the lens and is outside an irradiated region irradiated with the light emitted from the semiconductor light-emitting element toward the lens, the light-receiving element having a light-receiving surface and being configured to receive, on the light-receiving surface, part of the light reflected from the lens.

2. The optical module according to claim 1,
wherein the light-forming unit includes:
a plurality of the semiconductor light-emitting elements mounted on the base member;
a plurality of the lenses mounted on the base member and disposed so as to correspond to the respective semiconductor light-emitting elements;
a plurality of the light-receiving elements mounted on the base member and disposed so as to correspond to the respective semiconductor light-emitting elements; and
a filter mounted on the base member and configured to multiplex light beams from the plurality of semiconductor light-emitting elements.

3. The optical module according to claim 1,
wherein the semiconductor light-emitting element is a laser diode.

4. The optical module according to claim 3,
wherein the output power of the light formed by the light-forming unit is 50 mW or more.

5. The optical module according to claim 1,
wherein the base member includes a base plate, and
wherein the light-receiving element is mounted directly on the base plate.

6. The optical module according to claim 1,
wherein the light-receiving element is mounted between an edge of the irradiated region and reflected light that is light traveling along the edge of the irradiated region and reflected from the lens.

7. The optical module according to claim 1,
wherein the light receiving surface is inclined relative to an optical axis of the light so as to be oriented toward the lens.

8. An optical module comprising:
a semiconductor light-emitting element configured to emit light;
a lens configured to reflect part of the light emitted from the semiconductor light-emitting element and transmit part of the light; and
a light-receiving element mounted outside an irradiated region irradiated with the light emitted from the semiconductor light-emitting element toward the lens and configured to receive part of the light reflected from the lens.

9. An optical module comprising
a light-forming unit that forms light,
wherein the light-forming unit includes:
a base member including a base plate;
a semiconductor light-emitting element mounted on the base member and consisting of a laser diode configured to emit light;
a lens mounted on the base member, configured to reflect part of the light emitted from the semiconductor light-emitting element, and configured to transmit part of the light; and
a light-receiving element mounted on the base member at a position that is between the semiconductor light-emitting element and the lens and is outside an irradiated region irradiated with the light emitted from the semiconductor light-emitting element toward the lens and is inside reflected light that is light traveling along an edge of the irradiated region and reflected from the lens, the light-receiving element having a light-receiving surface and being configured to receive, on the light-receiving surface, part of the light reflected from the lens,
wherein the light-receiving element is mounted directly on the base plate.

10. The optical module according to claim 8,
wherein the light receiving element is mounted on the base member at a position that is between the semiconductor light-emitting element and the lens.
